(19) United States
(12) Patent Application Publication
(10) Pub. No.: US 2021/0091682 A1
(43) Pub. Date: Mar. 25, 2021

(54) Hybrid Electrostatic Actuator

(71) Applicant: Wisconsin Alumni Research Foundation, Madison, WI (US)

(72) Inventors: Hongrui Jiang, Madison, WI (US); Alireza Ousati Ashtiani, Madison, WI (US)

(21) Appl. No.: 16/582,686

(22) Filed: Sep. 25, 2019

(51) Int. Cl. H02N 1/00; G02B 3/14; G02B 5/24

(52) U.S. Cl. CPC H02N 1/002; G02B 5/24; G02B 3/14

(57) ABSTRACT

A hybrid electrostatic actuator for use in conjunction with microfluidic devices, microlenses, optical irises and flat panel displays is provided. The hybrid electrostatic actuator includes a substrate having an upper surface and an electrical conductor supported in spaced relation to the substrate. A fluid is received between the substrate and the electrical conductor. An electrostatic generator is configured to selectively apply a variable electrostatic force on the electrical conductor. The application of the variable electrostatic force on the electrical conductor displaces the fluid from between the substrate and the electrical conductor.

### REFERENCE TO GOVERNMENT GRANT

This invention was made with government support under CNS1329481 awarded by the National Science Foundation and EB019460 awarded by the National Institutes of Health. The government has certain rights in the invention.

### FIELD OF THE INVENTION

This invention relates generally to microfluidic devices, and in particular, to to hybrid electrostatic actuators for use in conjunction with microfluidic devices, microlenses, optical irises and flat panel displays.

### BACKGROUND AND SUMMARY OF THE INVENTION

Micro-Electro-Mechanical System (MEMS) actuators are devices that convert electrical energy to mechanical motion. These actuators are used in a variety of optical, RF, and industrial applications, including as a focusing mechanism for a microlens. For example, in a liquid tunable microlens with a deformable membrane, a relatively large amount of liquid must be displaced into a lens chamber such that the reactive force of the deformable membrane exerts a relatively high pressure in the lens chamber. To drive a liquid tunable microlens, a parallel plate capacitive actuator may be used. A parallel plate capacitive actuator includes a single moving plate and a fixed plate (usually fixed to a substrate). When a voltage is applied to the capacitor, the moving plate is attracted to the fixed plate thereby displacing any liquid received therebetween. This “pull-in” of the moving plate happens as a result of an imbalance between the spring force of the actuator and the electrostatic force applied onto plates.

It is well known that in a simple parallel plate capacitive actuator, pull-in instabilities occur the voltage applied is above a certain threshold. This phenomenon, is inherent in the nature of the device, usually limits the practical displacement of liquid to 10% of the gap between the moving and fixed plates. Ideally, if one can manipulate these forces in a controlled way, it becomes possible to create a stable actuator that provides a large displacement and force.

Alternatively, it has been contemplated to utilize zipping actuators to generate a sufficiently large displacement and force in optofluidic devices. Zipping actuators utilize a bendable plate positioned opposite the fixed electrode. When electrified, one end of the bendable plate is pulled-in to the fixed electrode thereby creating a high force at the other end of the bendable plate. In prior art designs, however, the initial gap between electrodes is non-uniform, thereby making it impractical for mass production.

In view of the foregoing, there exists an ongoing need for a hybrid electrostatic actuator which is simple to manufacture like a parallel plate capacitive actuator, but that can provide both high pressure and large liquid displacement like a zipping actuator.

Therefore, it is a primary object and feature of a present invention to provide a hybrid electrostatic actuator that may be used in conjunction with microfluidic devices, microlenses, optical irises and flat panel displays.

It is a further object and feature of the present invention to provide a hybrid electrostatic actuator that can provide both high pressure and large liquid displacement.

It is still a further object and feature of the present invention to provide a hybrid electrostatic actuator that simple and inexpensive to fabricate.

In accordance with present invention, a hybrid electrostatic actuator is provided. The hybrid electrostatic actuator includes a substrate having an upper surface and an electrical conductor supported in spaced relation to the substrate. A fluid is received between the substrate and the electrical conductor. An electrostatic generator is configured to selectively apply a variable electrostatic force on the electrical conductor. The application of the variable electrostatic force on the electrostatic conductor displaces the fluid from between the substrate and the electrical conductor.

The electrical conductor may be an electrode having first and second ends and extending along an axis. The electrode has a length. An anchor interconnects the electrical conductor and substrate. The anchor supports the second end of electrode. Application of the variable electrostatic force to the electrode causes the first end of the electrode to pull-in towards the substrate. The electrode is configured to urge the fluid from the between the substrate and the electrode as the electrode is pulled in towards the substrate. The electrode may have a variable stiffness along the length thereof or the electrode may have a consistent stiffness along the length thereof.

The actuator may also include an enclosure defining a chamber for receiving the electrical conductor and fluid therein. The chamber may be connectable to a downstream device such that fluid displaced in respond to the application of the variable electrostatic force to the electrical conductor is urged into the downstream device. Alternatively, the enclosure may be defined by a compliant membrane such that fluid displaced in respond to the application of the variable electrostatic force to the electrical conductor deforms the compliant membrane.

In accordance with a further aspect of the present invention, a liquid tunable microlens assembly is provided. The liquid tunable microlens assembly includes an enclosure defined by first and second spaced transparent panels defining a cavity therebetween. A compliant membrane is received within the cavity and is deformable in response to an electrostatic force. The membrane divides the cavity into first and second fluid chambers and defines a microlens. A first fluid is received in the first fluid chamber and has a first refractive index. A second fluid is received in the second fluid chamber and has a second refractive index. The second refractive index is different from the first refractive index. An electrostatic generator is configured to generate a variable electrostatic force. The variable electrostatic force deforms the membrane and varies a focal length of the microlens in response to the magnitude of the variable electrostatic force.

The first transparent panel and the compliant membrane may electrically conductive. The electrostatic generator includes a voltage source operatively connected between the first transparent panel and the compliant membrane to generate a selected voltage thereacross. The application of the selected voltage between the first transparent panel and the compliant membrane generates the variable electrostatic force. The variable electrostatic force causes a first portion of compliant membrane to pull-in towards the first transparent panel and a second portion of the compliant membrane to deform so as to vary the focal length of the microlens.

The microlens assembly may also include a resilient support and an anchor. The resilient support is engageable with the compliant membrane. The resilient support is configured to resist deformation of the first portion of the compliant membrane in response to the variable electrostatic force. The anchor may interconnect the first and. second transparent panels and partially defining the cavity within the enclosure.

Alternatively, the electrostatic generator may include an electrode disposed in alignment with a first portion of the compliant member. The first fluid may be conductive such that the application of a selected voltage by the electrostatic generator between the electrode and the first fluid generates the variable electrostatic force. The variable electrostatic force causes the first portion of compliant membrane pull-in towards the electrode and the second portion of the compliant membrane deforms to vary the focal length of the microlens. The electrode may have a radially changing areal density.

In accordance with a still further aspect of the present invention, a light valve is provided. The light valve includes a transparent panel and a compliant membrane interconnected to the transparent panel and defining a cavity. The compliant membrane is deformable in response to an electrostatic force. A light absorbing dielectric fluid is received in the cavity. An electrostatic generator is configured to generate a variable electrostatic force on a portion of the compliant membrane. The variable electrostatic force displacing the light absorbing dielectric fluid from between the portion of the compliant membrane and the transparent panel.

The portion of the compliant membrane has a dimension. The dimension of the portion of the compliant membrane varies in response to a magnitude of the variable electrostatic force. The electrostatic generator may include a transparent electrode extending along the transparent panel. Alternatively, the transparent panel and the compliant membrane may be electrically conductive. The electrostatic generator includes a voltage source operatively connected between the transparent panel and the compliant membrane to generate a selected voltage thereacross. The application of the selected voltage between the transparent panel and the compliant membrane generates the variable electrostatic force. The variable electrostatic force causes a first portion of compliant membrane to pull-in towards the transparent panel and a second portion of the compliant membrane to deform.

### BRIEF DESCRIPTION OF THE DRAWINGS

The drawings furnished herewith illustrate a preferred methodology of the present invention in which the above advantages and features are clearly disclosed as well as others which will be readily understood from the following description of the illustrated embodiment.

In the drawings:

FIG. 1 is an isometric view of a hybrid actuator in accordance with the present invention;

FIG. 2a is a schematic, side elevational view of the hybrid actuator of the present invention in an initial, non-actuated configuration;

FIG. 2b is a schematic, side elevational view of the hybrid actuator of the present invention after initial actuation;

FIG. 2c is a schematic, side elevational view of the hybrid actuator of the present invention fully actuated;

FIG. 3a is a schematic, side elevational view of an alternate embodiment of the hybrid actuator of FIG. 1 in an intermediate actuation;

FIG. 3b is a schematic, side elevational view of the alternate embodiment of the hybrid actuator of the present invention after initial actuation;

FIG. 3c is a schematic, side elevational view of the alternate embodiment of the hybrid actuator of the present invention fully actuated;

FIG. 4 is a schematic view of the hybrid actuator of the present invention;

FIG. 5 is an isometric view of a liquid tunable microlens assembly incorporating a hybrid actuator in accordance with the present invention;

FIG. 6 is a cross-sectional view of the liquid tunable microlens assembly taken along line 6-6 of FIG. 5;

FIG. 7 is a cross-sectional view of the liquid tunable microlens assembly of FIG. 6 showing actuation of the hybrid actuator incorporated therein;

FIG. 8a is a cross-sectional view of an alternate embodiment of a liquid tunable microlens assembly incorporating a hybrid actuator in accordance with the present invention;

FIG. 8b is a cross-sectional view of the liquid tunable microlens assembly of FIG. 8a showing initial actuation of the hybrid actuator incorporated therein;

FIG. 8c is a cross-sectional view of the liquid tunable microlens assembly of FIG. 8a showing full actuation of the hybrid actuator incorporated therein;

FIG. 8d is a cross-sectional view of the liquid tunable microlens assembly taken along line 8d-8d of FIG. 8a;

FIG. 9a is a cross-sectional view of a light valve incorporating a hybrid actuator in accordance with the present invention;

FIG. 9b is a cross-sectional view of the light valve of FIG. 9a showing initial actuation of the hybrid actuator incorporated therein;

FIG. 9c is a cross-sectional view of the liquid tunable microlens assembly of FIG. 9a showing full actuation of the hybrid actuator incorporated therein;

FIG. 10a is a cross-sectional view of an alternate embodiment of a light valve incorporating a hybrid actuator in accordance with the present invention;

FIG. 10b is a cross-sectional view of the light valve of FIG. 10a showing initial actuation of the hybrid actuator incorporated therein;

FIG. 10c is a cross-sectional view of the light valve of FIG. 10a showing full actuation of the hybrid actuator incorporated therein;

FIG. 10d is a cross-sectional view of the light valve taken along line 10d-10d of FIG. 10a; and

FIG. 11 is a schematic view of the hybrid actuator of the present invention incorporated into a first type of actuator operatively connected to a corresponding downstream device.

### DETAILED DESCRIPTION OF THE DRAWINGS

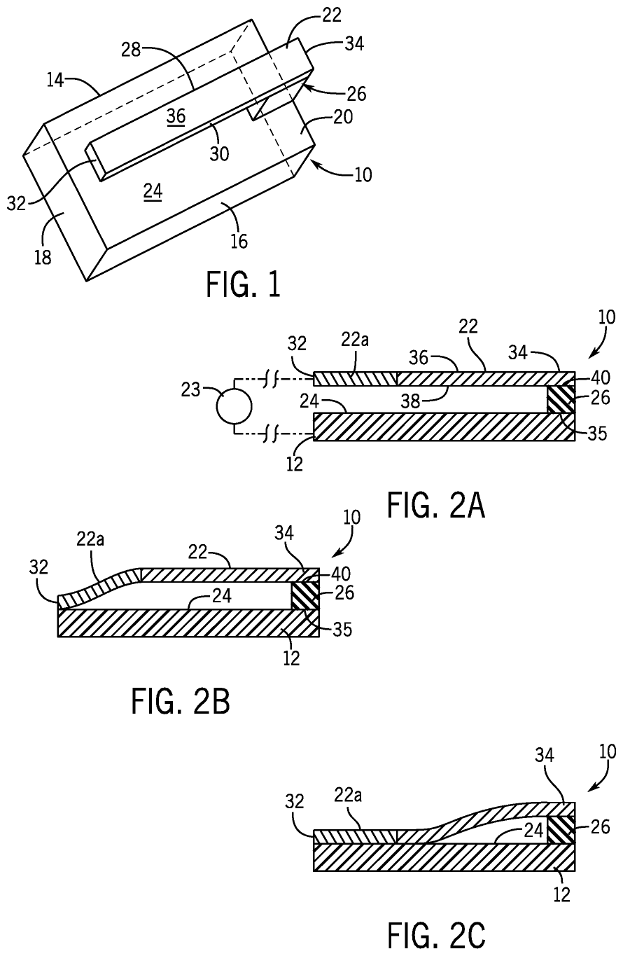

Referring to FIG. 1, a hybrid actuator in accordance with the present invention is generally designated by reference numeral 10. Hybrid actuator 10 includes substrate 12 and is defined by first and second sides 14 and 16, respectively, and first and second ends 18 and 20, respectively. However, it can be appreciated that substrate 12 may have other configurations without deviating from the scope of the present invention.

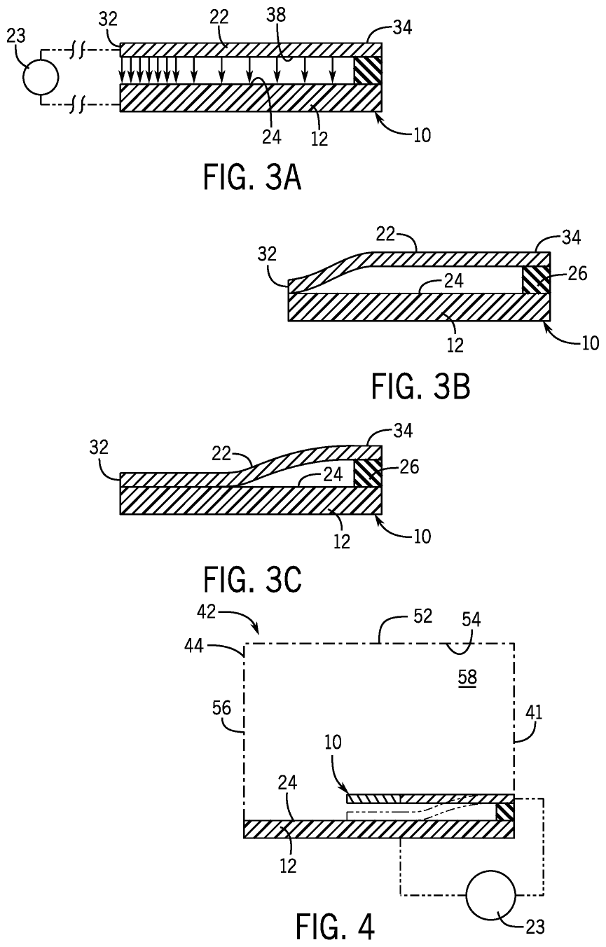

Hybrid actuator 10 further includes electrode 22 supported above upper surface 24 of substrate 12 by anchor 26. By way of example, electrode 22 may be defined by first and second sides 28 and 30, respectively, and first and second ends 32 and 34, respectively. However, it can be appreciated that electrode 22 may have other configurations without deviating from the scope of the present invention. As best seen in FIGS. 2a-2c and 3a-3c, electrode 22 includes upper surface 36 and lower surface 38 bonded to upper surface 40 of anchor 26 adjacent to second end 34 of electrode 22. Lower surface 35 of anchor 26 is bonded to upper surface 24 of substrate 12 such that electrode 22 is cantilevered over upper surface 24 of substrate 12.

It is contemplated for electrode 22 to fabricated from a homogeneous material, an alloy or be engineered to provide a varying stiffness as a function of location. For example, as best seen in FIGS. 2a-2c, electrode 22 may be fabricated from two different materials with dissimilar young modulus or with layers of different materials having different thicknesses (not shown), or a combination of both.

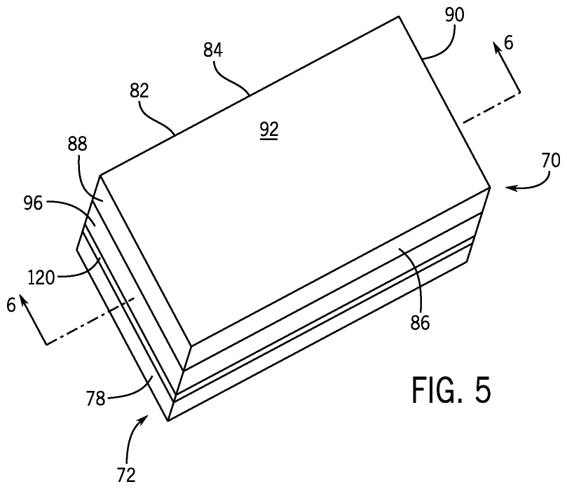

Referring to FIG. 4, hybrid actuator 10 may be received within an enclosure. Enclosure 41 includes cover 42 corresponding in size and shape to substrate 12. More specifically, cover 42 includes upper surface 52 and lower surface 54. The outer periphery 44 of cover 42 is sealably connected to substrate 12 by, for example, seal 56 so as to define a fluid chamber 58 between lower surface 54 of cover 42, upper surface 24 of substrate, and seal 56.

In operation, a fluid is provided in fluid chamber 58 of hybrid actuator 10. A voltage is applied between electrode 22 and substrate 12 by source 23 such that an electrostatic force is induced on electrode 22. In the event that electrode 22 is fabricated with varying stiffness as a function of location, the portion 22a of electrode 22 that is more compliant will tend to deform initially in response to the electrostatic force, FIG. 2b. After the electrostatic force exceeds a threshold, a pull-in of first end 32 of electrode 22 toward upper surface 24 of substrate 12 results. Thereafter, as the voltage is increased, electrode 22 behaves like a zipper, resulting in the electrostatic force causing a pull-in of electrode 22 toward upper surface 24 of substrate 12 from first end 32 to second end 34 thereof, FIG. 2c. It can be understood that movement of electrode 22 and/or the fluid urged from between electrode 22 and substrate 12 during the pull-in of electrode 22 may be used to actuate a desired downstream operation.

Referring to FIGS. 3a-3c, in the event that electrode 22 is fabricated with a relatively consistent stiffness as a function of location, it is contemplated for the electrostatic force exerted on electrode 22 to be non-uniform. In other words, electrostatic forces of different intensities may be applied at a given time to various portions of electrode 22. As a result, a pull-in will occur first at those portions of electrode 22 upon which the electrostatic forces with the greatest intensities are applied, FIG. 3a. For example, by increasing the electrostatic forces on electrode 22 from first end 32 to second end 34 thereof, electrode 22 will behave like a zipping actuator, thereby resulting in the pull-in of electrode 22 toward upper surface 24 of substrate 12 from first end 32 to second end 34 thereof, FIGS. 3b-3c. The electrostatic force may varied by providing different voltages between electrode 22 and substrate 12 or by designing a certain electrode pattern on substrate 12 to create a force that varies as a function of location, hereinafter described. It can be understood that operation of hybrid actuator 10 may be utilized to actuate a downstream device (not shown) in a conventional manner.

Referring to FIG. 5, a variation of hybrid actuator 10 may be incorporated into various devices such as a liquid tunable microlens assembly, generally designated by the reference numeral 70. Microlens assembly 70 includes transparent substrate 72 and is defined by parallel, first and second sides interconnected by first and second ends 78 and 80, respectively. As described, microlens assembly 70 has a generally rectangular, box-like configuration. However, it can be appreciated that microlens assembly 70 may have other configurations without deviating from the scope of the present invention.

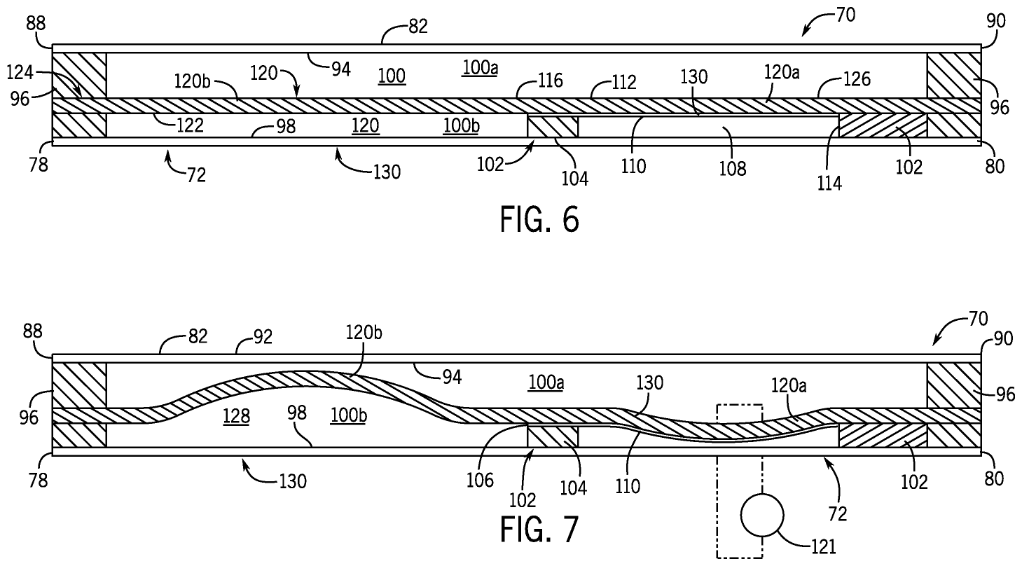

Microlens assembly 70 further includes a transparent cover 82 corresponding in size and shape to substrate 72. More specifically, cover 82 is defined by first and second sides 84 and 86 interconnected by first and second ends 88 and 90, respectively. Referring to FIGS. 6-7, cover 82 further includes upper surface 92 and lower surface 94. Seal 96 is positioned adjacent the outer peripheries of substrate 72 and cover 82 and sealably bonds lower surface 94 of cover 82 to upper surface 98 of substrate 72 so as to define fluid chamber 100 between lower surface 94 of cover 82, upper surface 98 of substrate 72 and seal 96.

Microlens assembly 70 further includes anchor 102 received within fluid chamber 100. Anchor 102 has a lower surface 104 bonded to upper surface 98 of substrate 72 and an upper surface 106. By way of example, anchor 102 has a generally ring-like structure having a circular configuration defining actuation chamber 108, however, other configurations are possible without deviating from the scope of the present invention. Elastic membrane 110 is supported above upper surface 98 of substrate 72 by anchor 102. By way of example, lower surface 112 of elastic membrane 110 adjacent second end 116 thereof may be interconnected to anchor 102 such that first end 114 of elastic membrane 110 is cantilevered over actuation chamber 108.

A hyperelastic membrane 120 is positioned within the interior of fluid chamber 100. Membrane 120 is defined by a first portion 120a which is electrically conductive and a non-conductive second portion 120b. By way of example, first portion 120a may include a thin, conductive film deposited thereon or therein to render first portion 120a electrically conductive. Membrane 120 includes a lower surface 122 bonded to upper surface 130 of elastic membrane 110 adjacent to first portion 120a, and an outer periphery 124 bonded to seal 96. Membrane 120 divides fluid chamber 100 into: 1) first fluid portion 100a defined by upper surface 126 of membrane 120 and lower surface 94 of cover 82 and being adapted for receiving a first fluid having a first refractive index and being an insulator therein; and 2) second fluid portion 100b defined by lower surface 122 of membrane 120 and upper surface 98 of substrate 72 and being adapted for receiving a second fluid having a second refractive index, different from the first refractive index, therein. Second fluid portion 100b of fluid chamber 100 includes actuation chamber 108 in communication with first portion 120a of membrane 120 and a lens portion 128 between seal 96 and anchor 102 in communication with second portion 120b of membrane 120. Actuation chamber 108 is in fluid communication with lens portion 128 of second fluid portion 100b of fluid chamber 100. First fluid in first fluid portion 100a, second fluid in lens portion 128 of second fluid portion 100b of fluid chamber 100, second portion 120b of membrane 120 define microlens 130 having a focal length.

In operation, elastic membrane 110 urges first portion 120a of membrane 120 towards an initial configuration, FIG. 6, wherein membrane 120 is generally planar and microlens 130 has an initial focal length. A voltage is applied by source 121 between substrate 72 and first portion 120a of membrane 120, as heretofore described, so as generate an electrostatic force on first portion 120a of membrane 120. Once the electrostatic force exceeds a threshold, a pull-in of the center of first portion 120a of membrane 120 toward upper surface 98 of substrate 72 results, FIG. 7. Thereafter, by varying the electrostatic force between substrate 72 and first portion 120a of membrane 120, e.g., by providing different voltages between substrate 72 and first portion 120a of membrane 120 or by designing a certain electrode pattern on substrate 12 to create a force that varies as a function of location, as hereinafter described, first portion 120a of membrane 120 behaves like a zipper, such that electrostatic force on first portion 120a of membrane 120 causes a pull-in of elastic membrane 110 toward upper surface 98 of substrate 72 radially outward from the center thereof toward anchor 102.

As first portion 120a of membrane 120 is pulled towards upper surface 98 of substrate 72, first portion 120a of membrane 120 urges the second fluid from actuation chamber 108 to lens portion 128 which, in turn, urges second portion 120b of membrane 120 toward lower surface 94 of cover 82. It can be understood that the change of shape of second portion 120b of membrane 120 changes the focal length of microlens 130. It is noted that by varying the electrostatic force on first portion 120a of membrane 120, the size of the first portion 120a of membrane 120 pulled towards upper surface 98 of substrate 72 may be controlled. In such manner, the focal length of microlens 130 may be adjusted to a desired focal length.

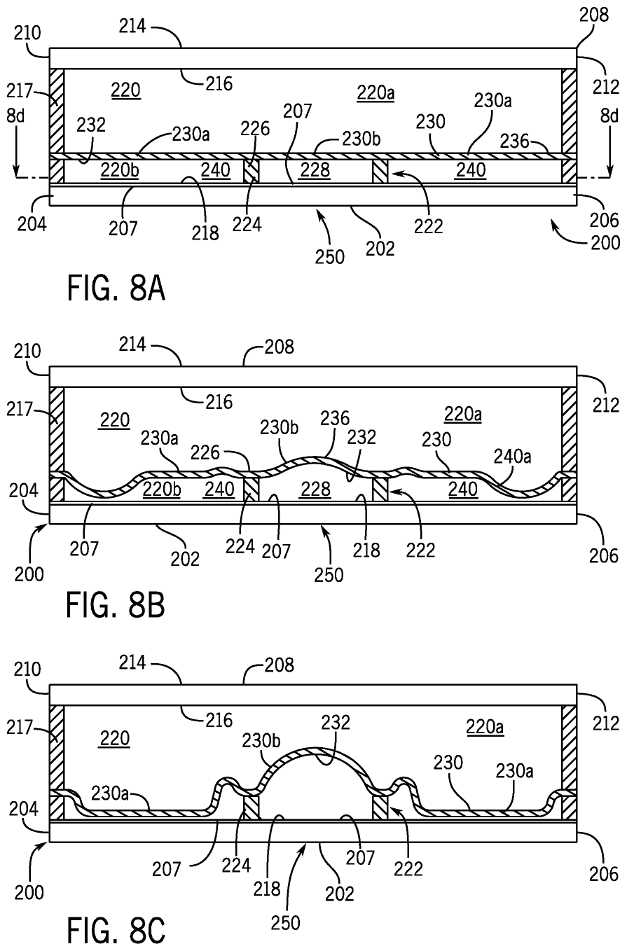

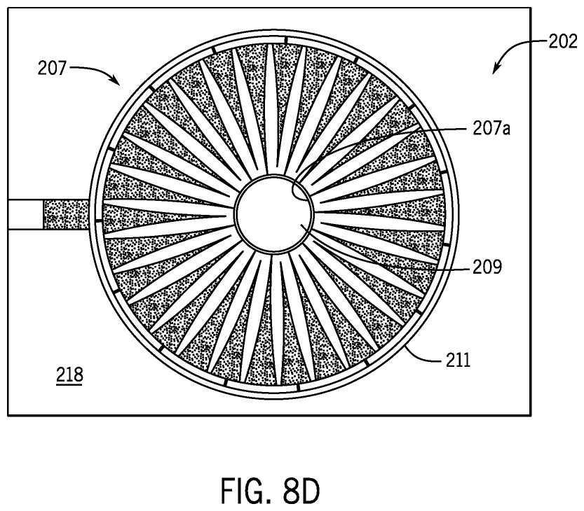

Referring to FIGS. 8a-8d, an alternate embodiment of a liquid tunable microlens assembly is generally designated by the reference numeral 200. Microlens assembly 200 includes transparent substrate 202 having opposite first and second ends 204 and 206, respectively, and an electrode 207 extending along upper surface 218 thereof. It is contemplated for microlens assembly 200 to have a generally square, box-like configuration. However, it can be appreciated that microlens assembly 200 may have other configurations without deviating from the scope of the present invention.

Referring to FIG. 8d, it is contemplated for electrode 207 to be a planar electrode having an inner edge 207a defining an opening 209 axially aligned with lens chamber 228, hereinafter described. Electrode 207 further includes a plurality of electrically connected electrode sections 211 arranged in a circular pattern on upper surface 218 of substrate 202 and extending radially outward from inner edge 207a. It is intended for the areal density of electrode 207 to increase radially from inner edge 207a thereof, for reasons hereinafter described.

Microlens assembly 200 further includes a transparent cover 208 corresponding in size and shape to substrate 202, including first and second ends 210 and 212, respectively. Cover 208 further includes upper surface 214 and lower surface 216. Seal 217 is positioned adjacent the outer peripheries of substrate 202 and cover 208 and interconnects/sealably bonds lower surface 216 of cover 208 to upper surface 218 of substrate 202, so as to define fluid chamber 220 between lower surface 216 of cover 208, upper surface 218 of substrate 202 and seal 217.

Microlens assembly 200 further includes anchor 222 received within fluid chamber 220. Anchor 222 has a lower surface 224 bonded to upper surface 218 of substrate 202 and an upper surface 226. By way of example, anchor 222 has a generally ring-like structure having a circular configuration defining lens chamber 228, however, other configurations are possible without deviating from the scope of the present invention. It is intended for anchor 222 to be porous to allow for the fluid to pass between lens chamber 228 and generally ring-shaped actuation chamber 240, for reasons hereinafter described.

Hyperelastic membrane 230 is positioned within the interior of fluid chamber 220. More specifically, membrane 230 includes a lower surface 232 bonded to upper surface 226 of anchor 222 and an outer periphery 235 interconnected/bonded to seal 217. Membrane 230 divides fluid chamber 220 into: 1) first fluid portion 220a defined by upper surface 236 of membrane 230 and lower surface 216 of cover 208 and being adapted for receiving a first conductive fluid, e.g., salinized water, having a first refractive index therein; and 2) second fluid portion 220b defined by lower surface 232 of membrane 230 and upper surface 218 of substrate 202 and being adapted for receiving a second insulative fluid, e.g., transparent oil, having a second refractive index, different from the first refractive index, therein.

Second fluid portion 220b of fluid chamber 220 includes: 1) a generally ring-shaped actuation chamber 240 extending between seal 217 and outer surface 242 of anchor 222 and communicating with a first portion 230a of membrane 230; and 2) lens chamber 228 defined within anchor 222 and communicating with a circular central, second portion 230b of membrane 230. Actuation chambers 240 is in fluid communication with lens chamber 228 of second fluid portion 220b of fluid chamber 220. First fluid in first fluid portion 220a, second fluid in lens chamber 228 of second fluid portion 220b of fluid chamber 220, and second portion 230b of membrane 230 define microlens 250 having a focal length.

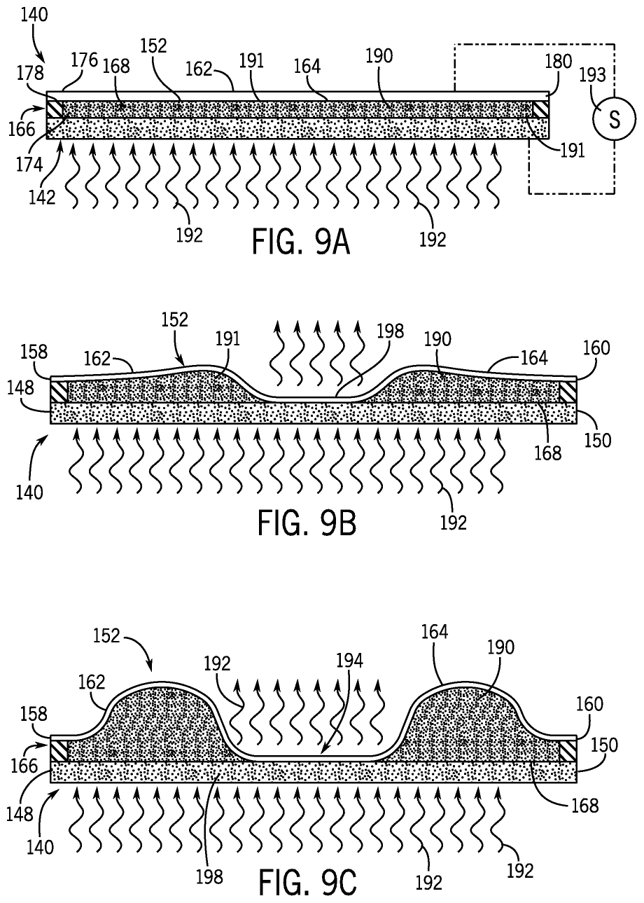

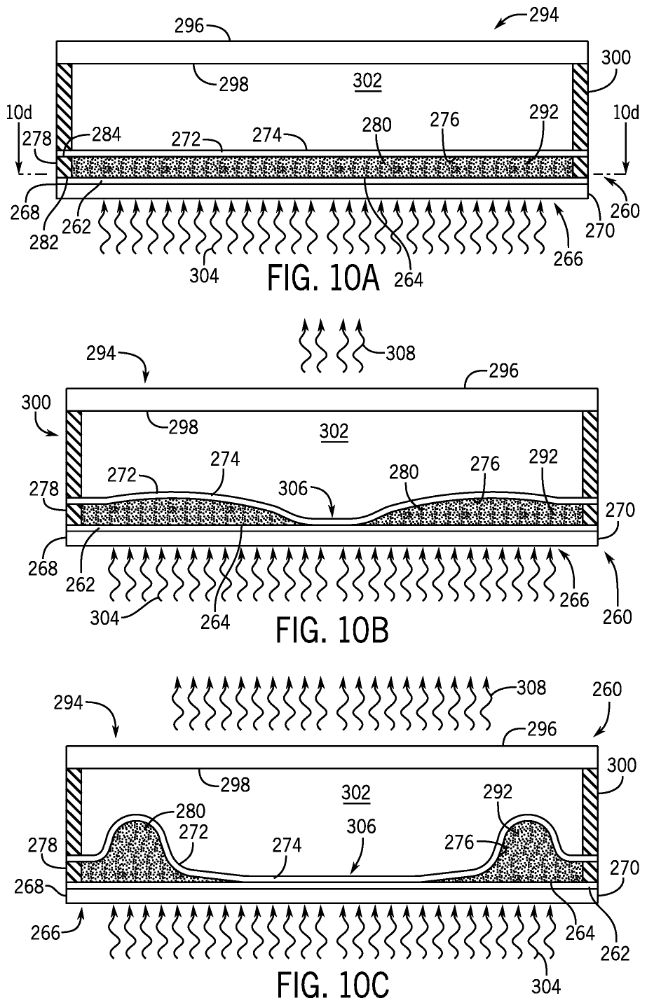

In operation, a voltage is applied by source (not shown) between electrode 207 and the first fluid, e.g., salinized water, in first fluid portion 220a so as generate an electrostatic force on first portion 230a of membrane 230 therebetween. Due to the increase in areal density of electrode 207 as electrode 207 extends radially outward from inner edge 207a thereof, the capacitance between electrode 207 and the first fluid increases as electrode 207 extends radially outward from inner edge 207a thereof. The increased capacitance between of electrode 207 and the first fluid as electrode 207 extends radially outward from inner edge 207a causes a greater electrostatic force on membrane 230 adjacent seal 217. Once the electrostatic force exceeds a threshold, a pull-in of first portions 230a of membrane 230 adjacent seal 217 toward upper surface 218 of substrate 202 results, FIG. 9b. Thereafter, an increase in the voltage between electrode 207 and the first fluid will increase the electrostatic force between of electrode 207 and the first fluid as electrode 207 will increase the electrostatic force on membrane 230 causing first portion 230a of membrane 120 to behave like zippers. In other words, the electrostatic force on first portion 230a of membrane 230 causes a pull-in of first portion 230a of membrane 230 toward upper surface 218 of substrate 202 radially inward toward anchor 222 at the center of microlens assembly 200, FIG. 9c.

As first portion 230a of membrane 230 is pulled toward upper surface 218 of substrate 202, first portion 230a of membrane 230 urges the second fluid from first actuation chamber 240 into lens chamber 228 through porous anchor 222, which, in turn, urges second portion 230b of membrane 230 toward lower surface 216 of cover 208. It can be understood that the change of shape of second portion 230b of membrane 230 changes the focal length of microlens 250. As such, by varying the magnitude and/or location of the voltage applied between electrode 207 and the first fluid, e.g., sanitized water, in first fluid portion 220a, the electrostatic forces on first portion 230a of membrane 230 may be varied, thereby controlling the amount of first portion 230a of membrane 230 that is pulled towards upper surface 218 of substrate 202. In such manner, the focal length of microlens 250 may be adjusted to a desired focal length.

It is further contemplated to incorporate the structure of a hybrid actuator of the present invention into a light valve, generally designated by the reference numeral 140, FIGS. 9a-9c. Light valve 140 includes electrically conductive, transparent substrate 142 defined by first and second sides interconnected by first and second ends 148 and 150, respectively. As described, light valve 140 has a generally rectangular, box-like configuration. However, it can be appreciated that light valve 140 may have other configurations without deviating from the scope of the present invention.

Light valve 140 further includes a transparent, compliant conductive membrane 152 corresponding in size and shape to substrate 142. More specifically, membrane 152 is defined by first and second sides 154 and 156, respectively, and first and second ends 158 and 160, respectively. Membrane 152 further includes upper surface 162 and lower surface 164. Anchor 166 is positioned adjacent the outer peripheries of substrate 142 and membrane 152 and bonds lower surface 164 of membrane 152 to upper surface 168 of substrate 142 so as to define fluid chamber 190 between lower surface 164 of membrane 152, upper surface 162 of substrate 142 and anchor 166. Fluid chamber 190 is adapted by receiving a light absorbing dielectric ink 191, for reasons hereinafter described.

Anchor 166 is defined by lower surface 174 bonded to upper surface 168 of substrate 142 and upper surface 176 bonded to lower surface 164 of membrane 152. By way of example, anchor 102 has a generally ring-like structure having rectangular configuration defined by first and second parallel end legs 178 and 180, respectively, interconnected by first and second parallel side legs 182 and 184, respectively, perpendicular thereto. It is noted that other configurations are possible without deviating from the scope of the present invention.

In operation, light rays 192 may be directed toward substrate 142 of light valve 140. It can be understood that light absorbing dielectric ink 191 in fluid chamber 190 of light valve 140 blocks all light rays 192 incident on substrate 142 from passing therethrough, FIG. 9a. Thereafter, a voltage may be provided by a source (not shown) across membrane 152 and substrate 142 at a desired location such that the electrostatic force exerted on membrane 152 causes the pull-in of membrane 152 toward upper surface 168 of substrate 142 at the desired location, FIG. 9b. It is intended for the increase of the electrostatic field on membrane 152 at the desired location initiates the collapse of membrane 152 from the desired location, leading to a zipping actuation. More specifically, such that electrostatic force on membrane 152 at the desired location causes a pull-in of membrane 152 toward upper surface 168 of substrate 142 radially outward from the desired location thereof toward anchor 166. As membrane 152 collapses onto upper surface 168 of substrate 142, membrane 152 urges the light absorbing dielectric ink from the central portion of fluid chamber 190 toward anchor 166. With membrane 152 collapsed onto upper surface 168 of substrate 142, FIG. 9c, transparent area 194 is provided in light valve 140. As such, a portion 196 of light rays 192 incident on central portion 198 of substrate 142 are allowed to pass through transparent area 194. By varying the voltage provided across membrane 152 and substrate 142, it can be appreciated that transparent area 194 may be varied to a desired dimension. Hence, as described, it can be appreciated that light valve 140 may act as a tunable optical valve.

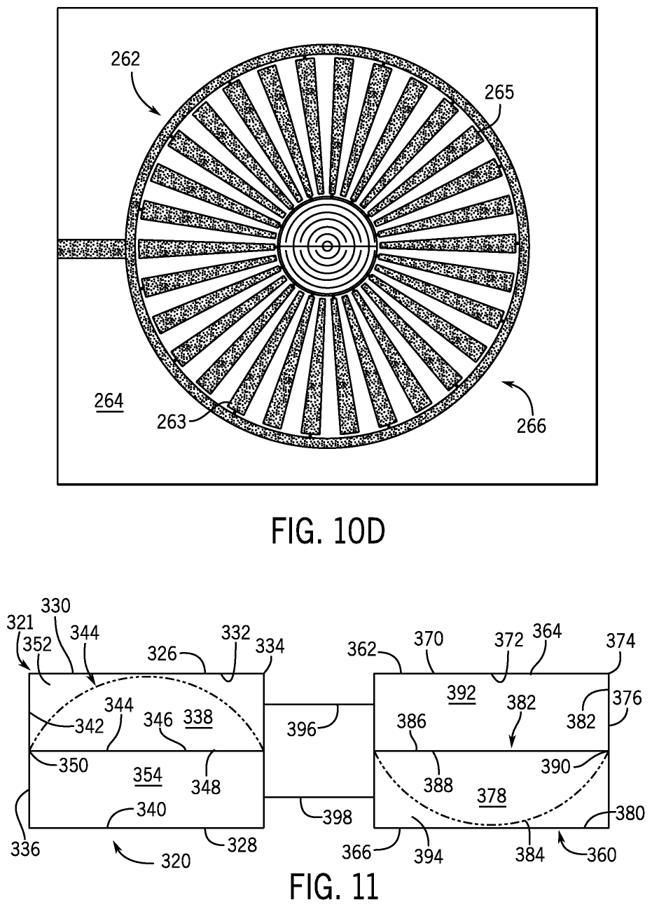

Referring to FIGS. 10a-10c, an alternate arrangement of a light valve incorporating a hybrid actuator is generally designated by the reference numeral 260. Light valve 260 includes transparent electrode 262 extending along upper surface 264 of transparent substrate 266 between first and second ends 268 and 270, respectively, thereof. More specifically, referring to FIG. 10d, it is contemplated for electrode 262 to be a planar electrode having a central portion 263 axially aligned with central portion 310 of substrate 266, hereinafter described. Electrode 262 further includes a plurality of electrically connected electrode sections 265 arranged in a circular pattern on upper surface 264 of substrate 266 and extending radially outward from central portion 263. It is intended for the areal density of electrode 262 to decrease radially from central portion 263, for reasons hereinafter described. As described, light valve 260 has a generally rectangular, box-like configuration. However, it can be appreciated that light valve 260 may have other configurations without deviating from the scope of the present invention.

Light valve 260 further includes a transparent, compliant membrane 272 corresponding in size and shape to substrate 266. Membrane 272 further includes upper surface 274 and lower surface 276. Anchor 278 is positioned adjacent the outer peripheries of substrate 266 and membrane 272 and bonds lower surface 276 of membrane 272 to upper surface 264 of substrate 266 so as to define first fluid chamber 280 between lower surface 276 of membrane 272, upper surface 264 of substrate 266 and anchor 278. First fluid chamber 280 is adapted by receiving a light absorbing dielectric ink 292, for reasons hereinafter described. More specifically, anchor 278 includes lower surface 282 bonded to upper surface 264 of substrate 266 and upper surface 284 bonded to lower surface 276 of membrane 272. By way of example, anchor 278 has a generally ring-like structure having rectangular configuration, but other configurations are possible without deviating from the scope of the present invention.

Light valve 260 further includes a transparent cover 294 corresponding in size and shape to substrate 266. Cover 294 is defined by upper surface 296 and lower surface 298. Seal 300 is positioned adjacent the outer periphery of cover 294 and interconnects/sealably bonds lower surface 298 of cover 294 to upper surface 274 of membrane 272 so as to define second fluid chamber 302 between lower surface 298 of cover 294, upper surface 274 of membrane 272 and seal 300. Second fluid chamber 302 is adapted by receiving a transparent conductive fluid, such as salinized water, therein, for reasons hereinafter described.

In operation, light rays 304 may be directed toward substrate 266 of light valve 260. It can be understood that light absorbing dielectric ink 292 in first fluid chamber 280 of light valve 260 blocks all light rays 304 incident on substrate 265 from passing therethrough, FIG. 10a. Thereafter, a voltage is applied by source (not shown) between electrode 262 and the fluid, e.g., salinized water, in second fluid chamber portion 302 such that an electrostatic force is exerted at a desired location on membrane 272, e.g., the portion of membrane 272 axially aligned with the center of electrode 262, causes the pull-in of membrane 272 toward upper surface 264 of substrate 256 at the desired location, FIG. 10b. It is intended for the increase of the electrostatic force on membrane 272, e.g. by increase the voltage across electrode 262 and the fluid in second fluid chamber portion 302, so as to initiate the collapse of membrane 272 from the desired location radially outward, leading to a zipping actuation. More specifically, electrostatic force on membrane 272 at the desired location causes a pull-in of membrane 272 toward upper surface 264 of substrate 266 radially outward toward anchor 278. As membrane 272 collapses onto upper surface 264 of substrate 266, membrane 272 urges the light absorbing dielectric ink from the central portion of first fluid chamber 280 toward anchor 278. With membrane 272 collapsed onto upper surface 264 of substrate 266, FIG. 10c, transparent area 306 is provided in light valve 260. As such, a portion 308 of light rays 304 incident on central portion 310 of substrate 266 are allowed to pass through transparent area 306. By varying the location and/or magnitude of the voltage applied to between electrode 262 and the conductive fluid, e.g., salinized water, in second fluid chamber 302, and hence, the electrostatic force on membrane 272, it can be appreciated that transparent area 306 may be varied to a desired dimension. In such manner, it can be appreciated that light valve 260 may be used as a tunable optical valve.

Referring to FIG. 11, it can be understood that the various embodiments of the hybrid actuator disclosed herein may be utilized to actuate a downstream device 320. Device 320 includes enclosure 321 having cover 326 corresponding in size and shape to substrate 328. Cover 326 includes upper surface 330 and lower surface 332. The outer periphery 334 of cover 326 sealably connected to substrate 328 by, for example, sidewall 336 so as to define a chamber 338 between lower surface 332 of cover 326, upper surface 340 of substrate 328, and inner surface 342 of sidewall 336.

Device 320 further includes a compliant membrane 344 corresponding in size and shape to substrate 328. More specifically, membrane 344 includes upper surface 346, lower surface 348 and outer periphery 350 sealably connected to inner surface 342 of sidewall 336. Membrane 344 divides chamber 338 into 1) first fluid portion 352 defined by upper surface 346 of membrane 344 and lower surface 332 of cover 326 and adapted for receiving a first fluid therein; and 2) second fluid portion 354 defined by lower surface 348 of membrane 344 and upper surface 340 of substrate 328 and adapted for receiving a second fluid therein.

Actuator 360 includes enclosure 362 having cover 364 corresponding in size and shape to conductive substrate 366. Cover 364 includes upper surface 370 and lower surface 372. The outer periphery 374 of cover 364 is sealably connected to substrate 366 by, for example, sidewall 376 so as to define a chamber 378 between lower surface 372 of cover 364, upper surface 380 of substrate 366, and inner surface 382 of sidewall 376.

Actuator 360 further includes an electrically conductive, compliant membrane 384 corresponding in size and shape to substrate 366. More specifically, membrane 384 includes upper surface 386, lower surface 388 and outer periphery 390 sealably connected to inner surface 382 of sidewall 366. Membrane 384 divides chamber 378 into 1) first fluid portion 392 defined by upper surface 386 of membrane 384 and lower surface 372 of cover 364 and adapted for receiving a first fluid therein; and 2) second fluid portion 394 defined by lower surface 388 of membrane 384 and upper surface 380 of substrate 366 and adapted for receiving a second fluid therein. First fluid portion 392 of chamber 378 of actuator 360 is fluidically connected to first fluid portion 352 of chamber 338 of device 320 by line 396. Similarly, second fluid portion 394 of chamber 378 of actuator 360 is fluidically connected to second fluid portion 354 of chamber 338 of device 320 by line 398.

In operation, a voltage may be provided by a source (not shown) across membrane 384 and substrate 366 of actuator 360 at a desired location such that the electrostatic force exerted on membrane 384 causes the central portion of membrane 384 toward upper surface 380 of substrate 366 (shown in phantom in FIG. 11). It is intended for the increase of the electrostatic field on membrane 384 at the desired location initiates the collapse of membrane 384 radially outward from the central portion thereof, leading to a zipping actuation. As membrane 384 of actuator 360 collapses onto upper surface 380 of substrate 366, membrane 384 urges second fluid from second fluid portion 394 of chamber 378 of actuator 360 into second fluid portion 354 of chamber 338 of device 320 through line 398.

As second fluid flows into second fluid portion 354 of chamber 338 of device 320, it can be appreciated that the second fluid will exert a force on membrane 344 of device 320, thereby causing membrane 344 to deform (shown in phantom in FIG. 11). It can be understood that the force associated with the deformation of membrane 344 may be used by device 320 to actuate a desired operation. As the second fluid in second fluid portion 354 of chamber 338 of device 320 causes membrane 344 to deform, membrane 344 urges the first fluid in first fluid portion 352 of chamber 338 of device 320 into first fluid portion 392 of chamber 378 of actuator 360 through line 396, thereby reducing the fluidic pressure in first fluid portion 352 of chamber 338 of device 320.

Upon termination of the voltage provided by the source (not shown) across membrane 384 and substrate 366 of actuator 360, membrane 384 of actuator 360 returns to its initial configuration thereby urging the first fluid from first fluid portion 392 of chamber 378 of actuator 360 into first fluid portion 352 of chamber 338 of device 320 through line 396. Similarly, with the fluidic pressure in second fluid portion 394 of chamber 378 of actuator 360 reduced, membrane 344 of device 320 returns to its initial configuration thereby urging the second fluid from second fluid portion 352 of chamber 338 of device 320 into second fluid portion 394 of chamber 378 of actuator 360 through line 398, such that device 320 and actuator 360 return to their initial configuration.

It is noted that any and all of the various actuators described above may be incorporated into the liquid tunable microlens and/or the light valves described herein. By way of example, it is contemplated replace the conductive substrates with a standard planar electrode or an electrode with a varying areal density deposited on the upper surface of a substrate in the various embodiments heretofore described. Further, it can be appreciated that a conductive fluid may be utilized instead of conductive first portion 120a of membrane 120 in microlens assembly 70. Likewise, a partially conductive membrane may replace the conductive fluid in first fluid portion 220a of fluid chamber 220 in microlens assembly 200 and a partially conductive membrane may replace the conductive fluid in second fluid chamber 302 in light valve 360. Hence, it can be understood that other variations are possible without deviating from the scope of the present invention.

Various modes of carrying out the invention are contemplated as being within the scope of the following claims particularly pointing out and distinctly claiming the subject matter that is regarded as the invention.

We claim:

1. A hybrid electrostatic actuator, comprising:
a substrate having an upper surface;
an electrical conductor supported in spaced relation to the substrate;
a fluid received between the substrate and the electrical conductor; and
an electrostatic generator configured to selectively apply a variable electrostatic force on the electrical conductor;
wherein application of the variable electrostatic force on the electrical conductor displaces the fluid from between the substrate and the electrical conductor.

2. The actuator of claim 1 wherein the electrical conductor is an electrode having first and second ends and extending along an axis, the electrode having a length.

3. The actuator of claim 2 further comprising an anchor interconnecting the electrical conductor and substrate, the anchor supporting the second end of electrode.

4. The actuator of claim 3 wherein application of the variable electrostatic force to the electrode causes the first end of the electrode to pull-in towards the substrate.

5. The actuator of claim 3 wherein the electrode is configured to urge the fluid from the between the substrate and the electrode as the electrode is pulled in towards the substrate.

6. The actuator of claim 2 wherein the electrode having a variable stiffness along the length thereof.

7. The actuator of claim 2 wherein the electrode has a consistent stiffness along the length thereof.

8. The actuator of claim 1 further comprising an enclosure defining a chamber for receiving the electrical conductor and fluid therein, the chamber being connectable to a downstream device such that fluid displaced in respond to the application of the variable electrostatic force to the electrical conductor is urged into the downstream device.

9. The actuator of claim 1 further comprising an enclosure defining a chamber for receiving the electrical conductor and fluid therein, the enclosure including a compliant membrane, wherein fluid displaced in respond to the application of the variable electrostatic force to the electrical conductor deforms the compliant membrane.

10. A liquid tunable microlens assembly, comprising:
an enclosure defined by first and second spaced transparent panels defining a cavity therebetween;
a compliant membrane received within the cavity and being deformable in response to an electrostatic force, the membrane dividing the cavity into first and second fluid chambers and defining a microlens;
a first fluid received in the first fluid chamber and having a first refractive index;
a second fluid received in the second fluid chamber and having a second refractive index, the second refractive index being different from the first refractive index; and
an electrostatic generator configured to generate a variable electrostatic force, the variable electrostatic force deforming the membrane and varying a focal length of the microlens in response to the magnitude of the variable electrostatic force.

11. The microlens assembly of claim 10 wherein:
the first transparent panel and the compliant membrane are electrically conductive;
the electrostatic generator includes a voltage source operatively connected between the first transparent panel and the compliant membrane to generate a selected voltage thereacross; and
the application of the selected voltage between the first transparent panel and the compliant membrane generates the variable electrostatic force, the variable electrostatic force causing a first portion of compliant membrane to pull-in towards the first transparent panel and a second portion of the compliant membrane to deform so as to vary the focal length of the microlens.

12. The microlens assembly of claim 11 further comprising a resilient support engageable with the compliant membrane, the resilient support configured to resist deformation of the first portion of the compliant membrane in response to the variable electrostatic force.

13. The microlens assembly of claim 10 wherein:
the electrostatic generator includes an electrode disposed in alignment with a first portion of the compliant member;
the first fluid is conductive; and
the application of a selected voltage by the electrostatic generator between the electrode and the first fluid generates the variable electrostatic force, the variable electrostatic force causes the first portion of compliant membrane pull-in towards the electrode and the second portion of the compliant membrane deforms to vary the focal length of the microlens.

14. The microlens assembly of claim 13 wherein the electrode has radially changing areal density.

15. The microlens assembly of claim 10 further comprising an anchor interconnecting the first and second transparent panels and partially defining the cavity within the enclosure.

16. A light valve, comprising:
a transparent panel;
a compliant membrane interconnected to the transparent panel and defining a cavity, the compliant membrane being deformable in response to an electrostatic force;
a light absorbing dielectric fluid received in the cavity; and
an electrostatic generator configured to generate a variable electrostatic force on a portion of the compliant membrane, the variable electrostatic force displacing the light absorbing dielectric fluid from between the portion of the compliant membrane and the transparent panel.

17. The light valve of claim 16 wherein the portion of the compliant membrane has a dimension, the dimension of the portion of the compliant membrane varying in response to a magnitude of the variable electrostatic force.

18. The light valve of claim 16 wherein the electrostatic generator includes an electrode extending along the transparent panel, the electrode being transparent.

19. The light valve of claim 16 further wherein the transparent panel is electrically conductive.

20. The light valve of claim 15 wherein:
the transparent panel and the compliant membrane are electrically conductive;
the electrostatic generator includes a voltage source operatively connected between the transparent panel and the compliant membrane to generate a selected voltage thereacross; and
the application of the selected voltage between the transparent panel and the compliant membrane generates the variable electrostatic force, the variable electrostatic force causing a first portion of compliant membrane to pull-in towards the transparent panel and a second portion of the compliant membrane to deform.
